(19) United States
(12) Patent Application Publication
(10) Pub. No.: US 2007/0295969 A1
(43) Pub. Date: Dec. 27, 2007

(54) LED device having a top surface heat dissipator

(76) Inventors: Tong-Fatt Chew, Penang (MY); Kee-Yean Ng, Penang (MY)

Correspondence Address: Kathy Manke;Avago Technologies Limited, 4380 Ziegler Road, Fort Collins, CO, 80525, US

(21) Appl. No.: 11/478,935

(22) Filed: Jun. 26, 2006

(51) Int. Cl. H01L 33/00

(52) U.S. Cl. 257/79

(57) ABSTRACT

An LED Device Having a Top Surface Heat Dissipator is provided. The LED Device Having a Top Surface Heat Dissipator includes a substrate body, and a light emitting diode over the substrate body. The LED Device Having a Top Surface Heat Dissipator also has an electrically and thermally conductive heat dissipator over the substrate body. A method of dissipating heat from an LED device is also provided.

### BACKGROUND OF THE INVENTION

Light emitting diode (“LED”) devices are useful for generating light output. LED devices may convert electricity into photonic emissions in the form of visible light more efficiently than can incandescent and fluorescent bulbs, and can be individually configured to generate light emissions at one or more pre-selected wavelengths or wavelength bands. An LED may be positioned in a concave base housing adapted to provide an initial focus for the light output from the LED. The LED can be provided with anode and cathode interconnections placing the LED in communication with an electrical circuit for supplying a bias voltage to the LED. The LED can be encapsulated in a composition intended to protect the LED from external contaminants and from being physically damaged or dislodged, and which can form part of a lens system for further focusing the light output of the LED. A substrate on which the LED rests can include a metallized portion underneath the LED that can serve to dissipate heat from the LED.

Along with light output, LED devices also generate heat. Despite typical design features of LED devices including those summarized above, LED devices are commonly prone to damage caused by buildup of heat generated from within the devices. Although metallized LED substrates are useful design elements that can be incorporated in LED devices and can serve to dissipate heat, these elements are often inadequate to maintain reasonably moderate temperatures in the devices. Excessive heat buildup can cause deterioration of compositions of the LED devices, such as encapsulants for the LED. Epoxy and silicone polymers, commonly used in LED encapsulant formulations, generally are poor heat conductors and are not sufficiently resistant to the high temperatures that often are generated inside LED devices during operation. These polymers can develop substantially reduced light transmissivity as they undergo heat degradation caused by such high temperatures. This reduced light transmissivity can increase internal absorbance by the LED devices of light at wavelengths that are intended to be output from the devices. This light absorbance can be pronounced at near-ultra-violet wavelengths, and can cause commensurate declines in light output quality and intensity from an LED device.

Consequently, there is a continuing need to provide new LED devices having improved capability to dissipate heat in order to protect against degradation of LED device elements.

### SUMMARY

An LED device incorporating a top surface heat dissipator (“LED Device Having a Top Surface Heat Dissipator”) is described. The LED Device Having a Top Surface Heat Dissipator includes a substrate body, and a light emitting diode (“LED”) over the substrate body. The LED Device Having a Top Surface Heat Dissipator also has an electrically and thermally conductive heat dissipator over the substrate body. As an example, the LED Device Having a Top Surface Heat Dissipator may include an optically transparent body over the electrically and thermally conductive heat dissipator.

As another example, a method of dissipating heat from an LED device is provided. The method includes forming an LED Device Having a Top Surface Heat Dissipator including a substrate body, a light emitting diode (“LED”) over the substrate body, and an electrically and thermally conductive heat dissipator over the substrate body; and dissipating heat generated by the LED through the electrically and thermally conductive heat dissipator.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. Moreover, in the figures, like reference numerals designate corresponding parts throughout the different views.

FIG. 1 is a top view showing an example of an implementation of an LED Device Having a Top Surface Heat Dissipator.

FIG. 2 is a cross-sectional view, taken on line 2-2, showing the LED Device Having a Top Surface Heat Dissipator as shown in FIG. 1.

FIG. 3 is a bottom view, taken on line 3-3, showing the LED Device Having a Top Surface Heat Dissipator shown in FIG. 1.

FIG. 4 is a bottom view, taken on line 4-4, showing a Top Surface Heat Dissipator including an optically transparent body and two electrically and thermally conductive heat dissipators in the LED Device Having a Top Surface Heat Dissipator shown in FIG. 1.

FIG. 5 is a flowchart showing an implementation example of a process for fabricating the LED Device Having a Top Surface Heat Dissipator shown in FIGS. 1-4.

FIG. 6 is a cross-sectional view, taken on line 2-2, showing an example of an implementation of another LED Device Having a Top Surface Heat Dissipator 600 having a modified structure and the same top view, shown in FIG. 1, as the LED Device Having a Top Surface Heat Dissipator 100.

### DETAILED DESCRIPTION

In the following description of various implementations, reference is made to the accompanying drawings that form a part of this disclosure, and which show, by way of illustration, specific implementations in which the invention may be practiced. Other implementations may be utilized and structural changes may be made without departing from the scope of the present invention.

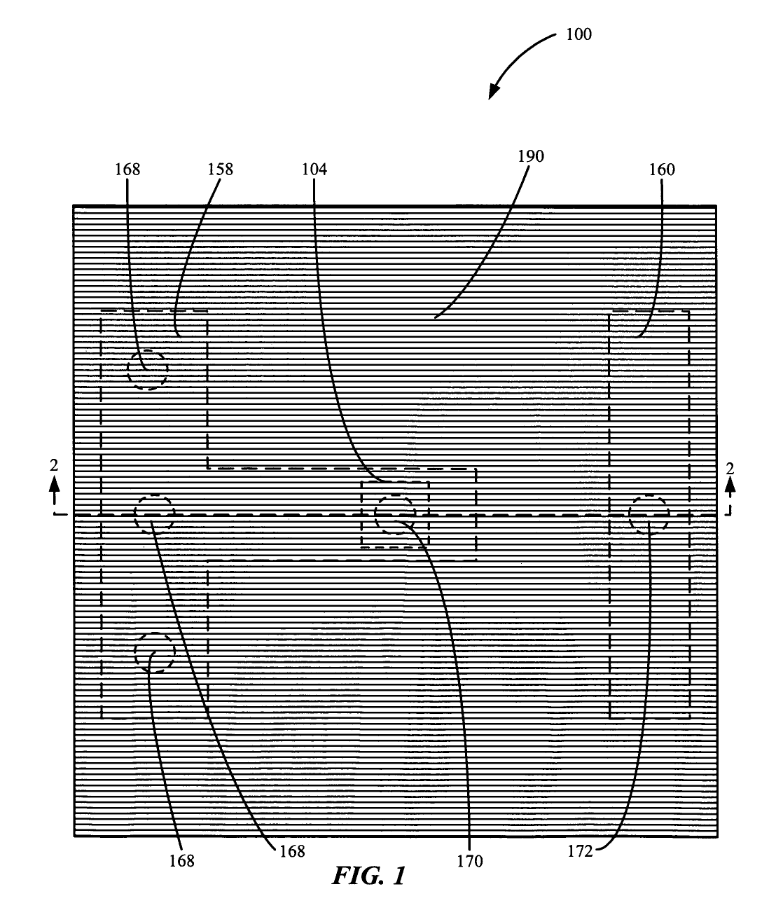

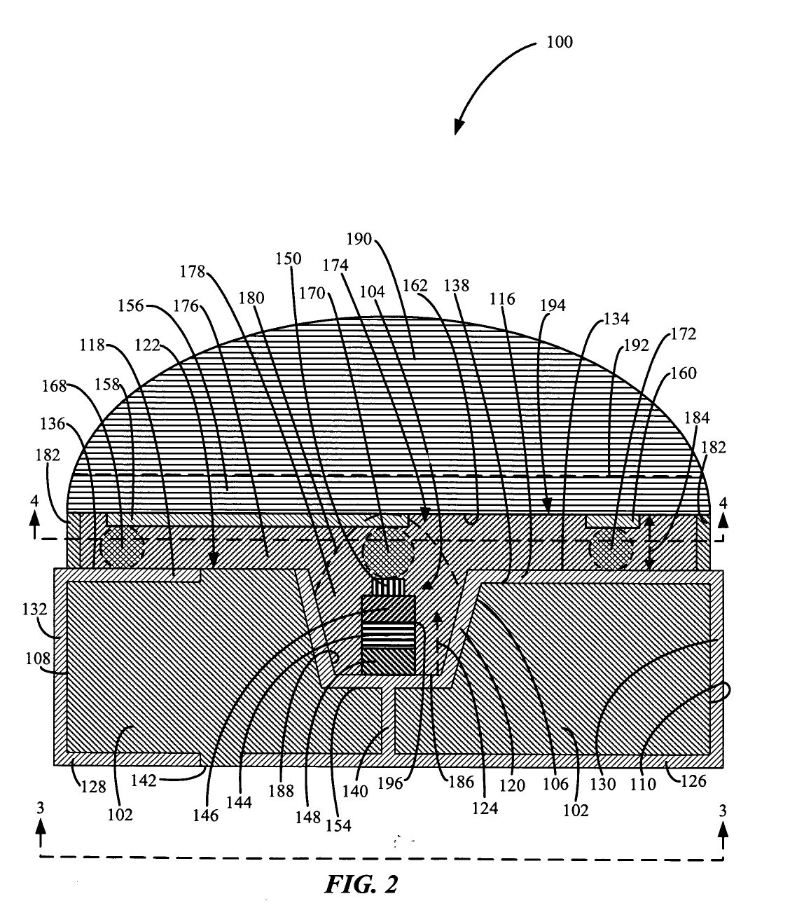

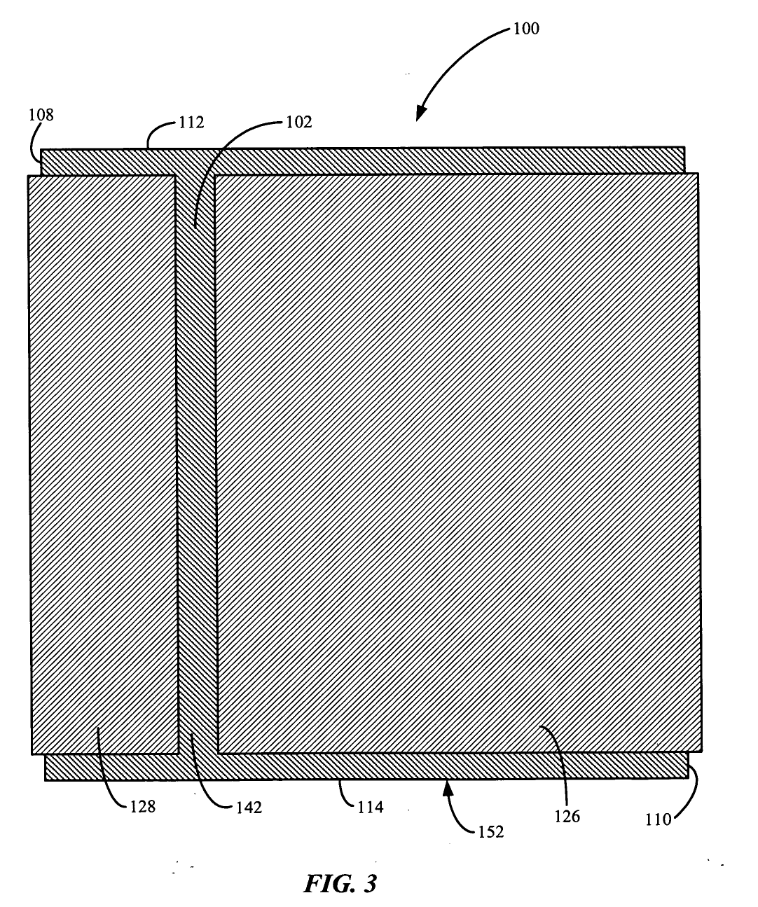

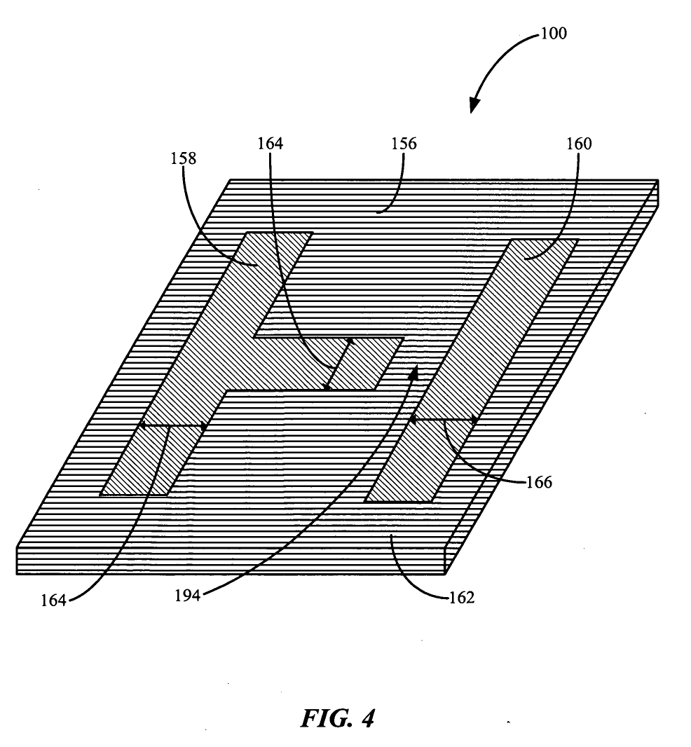

FIG. 1 is a top view showing an example of an implementation of an LED Device Having a Top Surface Heat Dissipator 100. FIG. 2 is a cross-sectional view, taken on line 2-2, showing the LED Device Having a Top Surface Heat Dissipator as shown in FIG. 1. FIG. 3 is a bottom view, taken on line 3-3, showing the LED Device Having a Top Surface Heat Dissipator shown in FIG. 1. FIG. 4 is a bottom view, taken on line 4-4, showing a Top Surface Heat Dissipator including an optically transparent body and two electrically and thermally conductive heat dissipators in the LED Device Having a Top Surface Heat Dissipator shown in FIG. 1.

The LED Device Having a Top Surface Heat Dissipator 100 includes a substrate body 102 on which an LED 104 is placed. As an example, the substrate body may include a concave cavity 106, and the LED 104 may be on the substrate body 102 in the concave cavity. The term “concave” as used throughout this specification means and refers to a cavity which is, as examples, bowl shaped or cup-shaped. As an example, the substrate body 102 may have rectangular lateral sides 108, 110, 112 and 114 as may be seen in FIG. 3. In another example, the lateral sides of the substrate body 102 may collectively form another shape, such as a pentagon, rectangle, circle or ellipse.

The LED Device Having a Top Surface Heat Dissipator 100 may include a cathode electrode 116 and an anode electrode 118. The cathode electrode 116 may be integrated with a conductive frame 120 lining the concave cavity 106, and a gap 122 may electrically isolate the cathode electrode 116 and the anode electrode 118 from each other. The conductive frame 120 may be, as an example, optically reflective to focus light generated by the LED 104 generally in the direction of the arrow 124. As examples, the conductive frame 120 may be plated with a composition including silver or including nickel and gold. In a further implementation, the cathode electrode 116 may include a surface mount (“SMT”) pad 126. As an example, the anode electrode 118 may include an SMT pad 128. It is understood that the respective locations of the SMT pads 126 and 128 with respect to the substrate body 102 may be varied. The cathode electrode 116 may include a connecting portion 130, and the anode electrode 118 may include a connecting portion 132. It is understood that the connecting portion 130 of the cathode electrode 116 and the connecting portion 132 of the anode electrode 118 may or may not be positioned fully or partially flush against the lateral sides 110 and 108, respectively, of the substrate body 102. In another implementation, a portion 134 of the cathode electrode 116 and a portion 136 of the anode electrode 118 may each be positioned over a top surface 138 of the substrate body 102. The cathode electrode 116 may include an internal portion 140 passing between the conductive frame 120 and the SMT pad 126.

In an alternative example (not shown) the cathode electrode 116 and the anode electrode 118 may pass through the substrate body 102 to a bottom surface 142 of the substrate body without exiting from any of the lateral sides 108, 110, 112 and 114 of the substrate body.

As another implementation (not shown), the concave cavity 106 may be omitted and the LED 104 may be on the top surface 138 of the substrate body 102.

The LED 104 may include a p-doped semiconductor body 144 and an n-doped semiconductor body 146. As an example, the shape of the LED 104, as seen in FIG. 1, may be a rectangular prism. In other examples, the shape of the LED 104 may be cubic, cylindrical, or have another selected geometric shape. As an example, more than one LED 104 may be placed in the concave cavity 106. In an implementation, an array of LEDs 104 may be placed in the concave cavity 106.

It is appreciated by those skilled in the art that the term “body” as used throughout this specification broadly means and includes all forms of a mass of a subject element of an LED Device Having a Top Surface Heat Dissipator, such as, for example, a layer, multiple layers, a coating, a casting, or a block, of any suitable dimensions, however formed.

The p-doped semiconductor body 144 may be in electrical communication with a base conductor body 148 and the n-doped semiconductor body 146 may be in electrical communication with a top conductor body 150. The base conductor body 148 and top conductor body 150 allow current to flow in and out of the p-doped semiconductor body 144 and n-doped semiconductor body 146, respectively.

It is appreciated that in an alternative example structure for the LED Device Having a Top Surface Heat Dissipator 100, the semiconductor body 146 may be p-doped and the semiconductor body 144 may be n-doped. A current flow through the LED 104 in such an alternative structure may be reversed, so that the LED Device Having a Top Surface Heat Dissipator 100 may include an anode electrode 116 and a cathode electrode 118. As another example, the cathode electrode 116 may be replaced by a first terminal electrode 116 at a relatively high electrical potential in electrical communication with the p-doped semiconductor body 144; and the anode electrode 118 may be replaced by a second terminal electrode 118 at a relatively low electrical potential in electrical communication with the n-doped semiconductor body 146.

A perimeter 152 of the substrate body 102 may be square as shown in FIG. 3. Alternatively (not shown), the perimeter 152 of the substrate body 102 may be circular, elliptical, pentagonal, or hexagonal, as examples. The SMT pads 126 and 128 conduct heat away from the LED 104 for dissipation into an adjacent material (not shown) on which the LED Device Having a Top Surface Heat Dissipator 100 may be supported, such as a printed circuit board. In an example (not shown), a bottom surface 154 of the conductive frame 120 lining the concave cavity 106 may be exposed adjacent to the bottom surface 142 of the substrate body 102 so that heat may be conducted away from the LED 104.

The LED Device Having a Top Surface Heat Dissipator 100 may further include an optically transparent body 156 positioned over the LED 104, the portion 134 of the cathode electrode 116, the portion 136 of the anode electrode 118, and the top surface 138 of the substrate body 102. By “optically transparent” throughout this specification is meant that a subject body may be formed of a composition having selected optical transmittance. As an example, the optical transmittance of the optically transparent body 156 may be selected dependent upon the intended end-use for the LED Device Having a Top Surface Heat Dissipator 100. As an implementation, the optically transparent body 156 may be formed of a composition selected for high transmission and low absorbance of the light wavelength or wavelengths emitted by the LED 104. In an example where the LED Device Having a Top Surface Heat Dissipator 100 may be a phosphor-conversion device to be utilized in an implementation to generate white light, the optically transparent body 156 may be formed of a composition selected for high transmission and low absorbance of the light wavelengths emitted by the LED 104 and of the light wavelengths emitted by the phosphor, as further discussed below.

An electrically and thermally conductive heat dissipator 158 may be integrated with the optically transparent body 156 and spaced apart in partial alignment over and facing the portion 136 of the anode electrode 118. The electrically and thermally conductive heat dissipator 158 is also spaced apart in partial alignment over and facing the top conductor body 150. A thermally conductive heat dissipator 160 may be integrated with the optically transparent body 156 and spaced apart in partial alignment over and facing the portion 134 of the cathode electrode 116. As an example, the electrically and thermally conductive heat dissipator 158 and the thermally conductive heat dissipator 160 may be formed on a bottom surface 162 of the optically transparent body 156 facing the top surface 138 of the substrate body 102. It is understood that the shapes of the electrically and thermally conductive heat dissipator 158 and the thermally conductive heat dissipator 160 may be varied from the examples shown in FIGS. 1, 2 and 4.

As an example, the electrically and thermally conductive heat dissipator 158 and the thermally conductive heat dissipator 160 may be formed from a composition that is optically transparent. In another implementation, the electrically and thermally conductive heat dissipator 158 and the thermally conductive heat dissipator 160 may be formed from an opaque composition such as a metal or a metal alloy. As an example where such an opaque composition may be utilized, a trace width indicated by the arrow 164 of the electrically and thermally conductive heat dissipator 158 and a trace width indicated by the arrow 166 of the thermally conductive heat dissipator 160 may be minimized, so that passage of light emissions from the LED through the optically transparent body 156 may be maximized. In another implementation, not shown, the electrically and thermally conductive heat dissipator 158 and the thermally conductive heat dissipator 160 may be partially or completely embedded into the bottom surface 162 of the optically transparent body 156.

One or a plurality of electrically and thermally conductive bodies 168 may be formed in contact with the portion 136 of the anode electrode 118 and with the electrically and thermally conductive heat dissipator 158. One or a plurality of electrically and thermally conductive bodies 170 may be formed in contact with the top conductor body 150 or with the semiconductor body 146 or both, and with the electrically and thermally conductive heat dissipator 158. The electrically and thermally conductive heat dissipator 158 is in electrical and thermal communication with the electrically and thermally conductive body 170 on one end, and in electrical and thermal communication with the electrically and thermally conductive body 168 on the other end. The electrically and thermally conductive heat dissipator 158 provides an electrical connection between the top conductor body 150 or the semiconductor body 146 or both and the anode electrode 118.

The electrically and thermally conductive body 170 provides a pathway for dissipation of heat through the electrically and thermally conductive heat dissipator 158. As another implementation (not shown), the electrically and thermally conductive body 170 may be embedded in the electrically and thermally conductive heat dissipator 158 or in the optically transparent body 156 or both. In another implementation, the electrically and thermally conductive body 170 may be embedded in the top conductor body 150 or in the semiconductor body 146 or both.

The electrically and thermally conductive body 168 may receive heat from the LED 104, originating along pathways including a pathway via the top conductor body 150 and the semiconductor body 146, the electrically and thermally conductive body 170, the electrically and thermally conductive heat dissipator 158 and the optically transparent body 156, for dissipation through the anode electrode 118 and the anode SMT pad 128. The electrically and thermally conductive heat dissipator 158 may also conduct heat through the optically transparent body 156 for dissipation.

As another example, the electrically and thermally conductive heat dissipator 158 may have a shape (not shown) placing the heat dissipator 158 in direct electrical and thermal communication with the top conductor body 150 or the semiconductor body 146, and the portion 136 of the anode electrode 118. In that example, the electrically and thermally conductive bodies 170 and 168 may be omitted.

In another example, one or a plurality of thermally conductive bodies 172 may be formed in contact with the portion 134 of the cathode electrode 116 and with the electrically and thermally conductive heat dissipator 158 and the thermally conductive heat dissipator 160. The thermally conductive body 172 may receive heat from the LED 104 originating along pathways including a pathway via the conductive frame 120 in contact with the base conductor body 148, and may conduct heat to the thermally conductive heat dissipator 160 for dissipation through the optically transparent body 156.

As a further implementation, the thermally conductive heat dissipator 160 may have a shape (not shown) placing the heat dissipator 160 in direct electrical and thermal communication with the portion 134 of the cathode electrode 116, and the thermally conductive body 172 may be omitted.

As examples, the electrically and thermally conductive bodies 168 and 170 and the thermally conductive body 172 may each be formed as a solder bump, a solder paste coating, or an anisotropic conductive film (ACF).

As an example, the top surface 138 of the substrate body 102, the portion 136 of the anode electrode 118, the portion 134 of the cathode electrode 116, the conductive frame 120, the bottom surface 162 of the optically transparent body 156, the electrically and thermally conductive heat dissipator 158, and the thermally conductive heat dissipator 160, may together form a cavity 174. In an implementation, the cavity 174 may be completely or partially filled by a filler body 176. The filler body 176 may be optically transparent. In an example, the filler body 176 may be formed from a thermally conductive and electrically insulating composition that provides additional pathways for conduction of heat generated by the LED 104 to the electrically and thermally conductive heat dissipator 158, the thermally conductive heat dissipator 160, and the optically transparent body 156.

The filler body 176 may be formed of a composition having selected optical transmittance. As an example, the filler body 176 may be formed of a composition selected for high transmission and low absorbance of light wavelengths emitted by the LED 104 and of light wavelengths emitted by any phosphor, discussed below, that may be dispersed in the filler body 176 or otherwise located in the cavity 174. As an example, the filler body 176 may be formed of a curable polymeric resin, such as an epoxy, silicone or acrylate resin (such as polymethyl-methacrylate for example), or a mixture of such resins. In an example, the filler body 176 may be formed of another photon transmissive composition, such as an inorganic glass that may be applied in the form of a sol-gel, for example.

In another example, the filler body 176 may include a first stage optically transparent filler body 178 located as an example surrounding the LED 104 and extending to the dotted line 180; and a second stage thermally conductive filler body in the remaining portion of the cavity 174 outside the dotted line 180. The first stage optically transparent filler body 178 may thus surround the LED 104, and the second stage filler body in the remainder of the cavity 174 may thus surround the first stage filler body 178. In an implementation, the first stage optically transparent filler body 178 may make contact with the electrically and thermally conductive heat dissipator 158. As an example, the second stage filler body may be formed from an optically opaque composition including materials having high thermal conductivity such as particles of ceramics, metal oxides, silicates, nitrides, carbonates, mixtures, and the like.

In an example, the optically transparent body 156 may be spaced apart by a raised region 182 of the substrate body 102 from the portion 134 of the cathode electrode 116 and from the portion 136 of the anode electrode 118 at a distance indicated by the arrow 184. As another example, the raised region 182 may be omitted.

The concave cavity 106 may form a reflector for photons emitted by the LED 104. The reflector may generally deflect these photons in the direction of the arrow 124, indicating an orientation of maximum photonic radiation from the LED Device Having a Top Surface Heat Dissipator 100. As an example, a base inner wall 186 of the concave cavity 106 may have a circular circumference and a side inner wall 188 of the concave cavity 106 may also have a circular circumference that may, as examples, be substantially uniform along or expand in the direction of the arrow 124. It is appreciated by those skilled in the art, however, that the base inner wall 186 and the side inner wall 188 may also have circumferences of other shapes and orientations. For example, the base inner wall 186 may have a circumference that is elliptical, quadrilateral, or of some other geometric shape. As an example, the circumference of the base inner wall 186 may have at least one axis of symmetry, and the shape of the circumference of the side inner wall 188 may be similar to that of the base inner wall 186.

As an example, a lens body 190 may be formed over and in contact with the optically transparent body 156 at an interface indicated by the dotted line 192. The lens body 190 may serve to further focus the photonic emissions from the LED Device Having a Top Surface Heat Dissipator 100. It is understood that the lens body 190 may have a variety of shapes, and may be in the form of a Fresnel lens for example. In an implementation, the lens body 190 and the optically transparent body 156 may be integrally formed of a composition having selected optical transmittance. In that case, the interface indicated by the dotted line 192 may be omitted. As another example, the lens body 190 may be a diffused lens. The diffused lens may include dispersed light-scattering particles such as titanium dioxide or silicon dioxide particles, or particles of another metal oxide, as examples.

The substrate body 102 may be formed of a composition including a composition having a selected high dielectric constant. In an example, the dielectric constant may be sufficiently high so as to minimize a leakage current between the cathode electrode 116 and the anode electrode 118. In another implementation, the substrate body 102 may further be formed of a composition having a selected thermal conductivity sufficient to contribute to the dissipation of heat generated by the LED 104 from the LED Device Having a Top Surface Heat Dissipator 100. As examples, the substrate body 102 may be formed of a composition including alumina, aluminum nitride, aluminum silicate or sillimanite, barium neodymium titanate, barium strontium titanate (BST), barium tantalate, barium titanate (BT), beryllia, boron nitride, calcium titanate, calcium magnesium titanate (CMT), glass ceramic, cordierite/magnesium aluminum silicate, forsterite/magnesium silicate, lead magnesium niobate (PMN), lead zinc niobate (PZN), lithium niobate (LN), magnesium silicate, magnesium titanate, niobate or niobium oxide, porcelain, quartz, sapphire, strontium titanate, silica or silicate, steatite, tantalate or tantalum oxide, titania or titanate, zircon, zirconia or zirconate, zirconium tin titanate, FR4, polyimide, bismaleide triazine, or a mixture.

The electrically and thermally conductive heat dissipator 158 and the thermally conductive heat dissipator 160 may be formed of a composition having a selected high thermal conductivity. As an example, the composition may further have a selected high optical transparency at wavelengths of light emitted by the LED 104. The electrically and thermally conductive heat dissipator 158 is also formed from a composition that is electrically conductive. In an implementation, the composition selected for forming the thermally conductive heat dissipator 160 may happen, as a result of its selection for high thermal conductivity, to also be electrically conductive. In such an implementation, a gap 194 may be interposed between the electrically and thermally conductive heat dissipator 158 and the thermally conductive heat dissipator 160, and the optically transparent body 156 may be formed of a composition having a selected high dielectric constant. In this manner, a leakage current between the electrically and thermally conductive heat dissipator 158 and the thermally conductive heat dissipator 160 may be minimized. In an example, the electrically and thermally conductive heat dissipator 158 and the thermally conductive heat dissipator 160 may be formed of an electrically conductive oxide composition, such as a composition including indium-tin oxide, tin oxide, zinc oxide, zirconium oxide, zinc tin oxide, indium gallium zinc oxide, or a mixture. In another implementation, the electrically and thermally conductive heat dissipator 158 and the thermally conductive heat dissipator 160 may be formed of a metal composition, such as a composition including gold, silver, platinum, palladium, nickel, or an alloy. As an alternative implementation, the thermally conductive heat dissipator 160 may be formed from a composition that is not electrically conductive. In this implementation, the gap 194 may be omitted.

The optically transparent body 156 may be formed of a composition having a selected optical transparency at light wavelengths emitted by the LED 104. In an implementation, the composition may further have a selected high thermal conductivity. As an example, the optically transparent body 156 may be formed of a composition including an optically transparent ceramic such as an inorganic oxide which may include silicon dioxide for example, or an optically transparent high temperature polymer, liquid crystal polymer, polymer blend, or optically transparent ceramic composition. As an implementation, the optically transparent body 156 may be formed in-situ from an inorganic sol-gel composition.

With regard to the LED 104 itself, photon-emitting diode p-n junctions may typically be based on two selected mixtures of Group III and Group V elements, such as gallium arsenide, gallium arsenide phosphide, gallium nitride or gallium phosphide. Careful control of the relative proportions of these compounds, and others incorporating aluminum and indium, as well as the addition of dopants such as tellurium and magnesium, may enable production of LEDs that emit, for example, red, orange, yellow, or green light. As an example, the following semiconductor compositions (designated by epitaxial layers/LED substrate body) may be utilized to generate photons in the corresponding output wavelength ranges and colors indicated in parentheses: gallium-aluminum-arsenide/gallium arsenide (860 nm, infrared); gallium-aluminum-arsenide/gallium-aluminum-arsenide (660 nm, ultra red); aluminum-gallium-indium-phosphide (633 nm, super red); aluminum-gallium-indium-phosphide (612 nm, super orange); gallium-arsenide/gallium-phosphide (605 nm, orange); gallium-arsenide-phosphide/gallium-phosphide (585 nm, yellow); indium-gallium-nitride/silicon-carbide; indium-gallium-nitride/silicon-carbide; indium-gallium-nitride/silicon-carbide; gallium-phosphide/gallium-phosphide (555 nm, pure green); gallium-nitride/silicon-carbide (470 nm, super blue); gallium-nitride/silicon-carbide (430 nm, blue violet); and indium-gallium-nitride/silicon-carbide (395 nm, ultraviolet). It is understood that two selected mixtures of Group II and Group VI elements or a mixture of Group IV elements may alternatively be utilized.

For operation of the LED Device Having a Top Surface Heat Dissipator 100, the SMT pad 126 of the cathode electrode 116 and the SMT pad 128 of the anode electrode 118 may be placed in electrical communication with conductive elements of an external circuit (not shown) which are, as an example, located on a surface such as a printed circuit board. In an implementation, the conductive elements may be conductive pads. In an example of operation, a bias current may be applied across the cathode electrode 116 and the anode electrode 118 by an external power source, not shown. The bias current may induce charge carriers to be transported across an interface 196 between the n-doped semiconductor body 146 and the p-doped semiconductor body 144. Electrons may flow from the n-doped semiconductor body 146 to the p-doped semiconductor body 144, and holes may be generated in the opposite direction. Electrons injected into the p-doped semiconductor body 144 may recombine with the holes, resulting in electroluminescent emission of photons from the LED 104.

As a further example, the LED Device Having a Top Surface Heat Dissipator 100 may be a phosphor-converting LED device having a selected phosphor composition dispersed in a region of or throughout the filler body 176. The selected phosphor composition may as an example be dispersed in a suitable encapsulant in a liquid phase and then deposited in the cavity 174.

In an example of operation, electroluminescent emissions from the LED 104 itself at one wavelength may be partially intercepted by the phosphor, resulting in stimulated luminescent emissions from the phosphor that may as an example be at a longer wavelength than that of the electroluminescent emissions. Photons emitted by the LED 104 at a first wavelength and by the phosphor at a second wavelength may then be additively emitted from the LED Device Having a Top Surface Heat Dissipator 100. It is appreciated by those skilled in the art that the LED 104 as an example may be designed to emit blue photons, and the phosphor composition may be designed to emit yellow photons, in ratios where the additive output may be perceived by the human eye as white light.

As an example, if photonic emissions interpreted by the human eye as white light are selected, the LED 104 may be designed to emit blue light. Gallium nitride-(“GaN—”) or indium-gallium-nitride (“InGaN—”) based LED semiconductor chips emitting blue light with an emission maximum broadly within a range of about 420 nanometers (“nm”) to about 490 nm, or more particularly within a range of about 430 nm to about 480 nm, may be utilized. The term “GaN- or InGaN-based LED” is to be understood as being an LED whose radiation-emitting region contains GaN, InGaN, or either or both of these nitrides together with other related nitrides, as well as compositions further including mixed crystals based on any of these nitrides, such as Ga(Al—In)N, for example. Such LEDs are known, for example, from Shuji Nakamura and Gerhard Fasol, “The Blue Laser Diode”, Springer Verlag, Berlin/Heidelberg, 1997, pp. 209 et seq., the entirety of which hereby is incorporated herein by reference. In another example, a polymer LED or a laser diode may be utilized instead of the semiconductor LED. It is appreciated that the term “light emitting diode” is defined as encompassing and including, as examples, semiconductor light emitting diodes, polymer light emitting diodes, and laser diodes.

The choice of phosphor compositions for excitation by some of the blue photons emitted by the LED 104 also may be determined by the selected end use application for the LED Device Having a Top Surface Heat Dissipator 100. As an example, if photonic emissions interpreted by the human eye as white light are selected, the selected phosphor may be designed to emit yellow light. When combined in appropriate ratios at appropriate wavelengths as shown, for example, in chromaticity charts published by the International Commission for Illumination, the blue and yellow photons may appear together to the eye as white light. In this regard, yttrium aluminum garnet (“YAG”) is a common host composition, and is usually doped with one or more rare-earth elements or compounds. Cerium is a common rare-earth dopant in YAG phosphors utilized for white light emission applications.

As an example, the selected phosphor composition may be a cerium-doped yttrium-aluminum garnet including at least one element such as yttrium, lutetium, selenium, lanthanum, gadolinium, samarium, or terbium. The cerium-doped yttrium-aluminum garnet may also include at least one element such as aluminum, gallium, or indium. As an example, the selected phosphor may have a cerium-doped garnet structure A₃B₅O₁₂, where the first component “A” represents at least one element such as yttrium (“Y”), lutetium (“Lu”), selenium (“Se”), larithanum (“La”), gadolinium (“Gd”), samarium (“Sm”), or terbium (“Tb”) and the second component “B” represents at least one element such as aluminum (“Al”), gallium (“Ga”), or indium (“In”). These phosphors may be excited by blue light from the LED 104 and in turn may emit light whose wavelength is shifted into the range above 500 nm, ranging up to about 585 nm. As an example, a phosphor may be utilized having a wavelength of maximum emission that is within a range of about 550 nm to about 585 nm. In the case of cerium-activated Tb-garnet luminescent compositions, the emission maximum may be at about 550 nm. Relatively small amounts of Tb in the host lattice may serve the purpose of improving the properties of cerium-activated luminescent compositions, while larger amounts of Tb may be added specifically to shift the emission wavelength of cerium-activated luminescent compositions. A high proportion of Tb is therefore well suited for white phosphor-converted LED devices with a low color temperature of less than 5000 K. For further background information on phosphors for use in phosphor-converted LED devices, see for example: published Patent Cooperation Treaty documents WO 98/05088; WO 97/50132; WO 98/12757; and WO 97/50132, which are herein incorporated by reference in their entirety.

As an example, a blue-emitting LED 104 based on gallium nitride or indium-gallium nitride, with emission maxima within a range of about 430 nm to about 480 nm, may be utilized to excite a luminescent composition of the YAG:Ce type with emission maxima within a range of about 526 nm to about 585 nm.

Various examples have been described where an LED Device Having a Top Surface Heat Dissipator 100 may be designed to combine blue photons generated by electroluminescence emitted by LED 104 with yellow photons generated from blue photon-stimulated luminescence of a phosphor element, in order to provide light output having a white appearance. However, it is appreciated that LED Devices Having a Top Surface Heat Dissipator 100 operating with different chromatic schemes may also be designed for producing light that appears to be white or appears to have another color. Light that appears to be white may be realized through many combinations of two or more colors generated by LED 104 electroluminescence and photon-stimulated phosphor luminescence. One example method for generation of light having a white appearance is to combine light of two complementary colors in the proper power ratio.

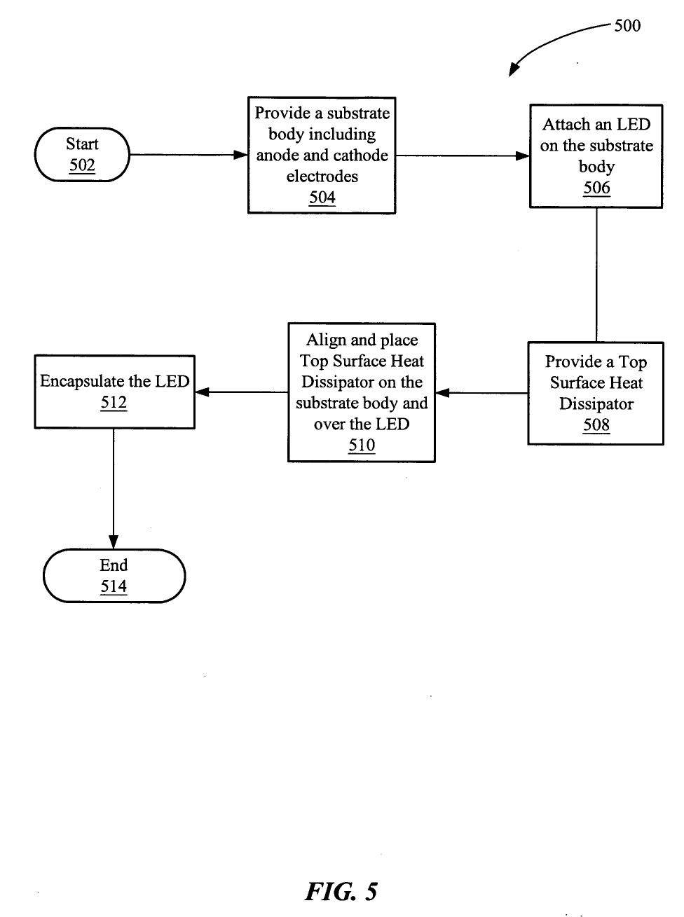

FIG. 5 is a flowchart showing an implementation example of a process 500 for fabricating the LED Device Having a Top Surface Heat Dissipator 100 shown in FIGS. 1-4. The process starts at step 502, and at step 504 a substrate body 102 may be provided. The substrate body 102 may include a concave cavity 106, and includes anode and cathode electrodes 118 and 116. The cathode electrode 116 may have an integrated conductive frame 120. The cathode and anode electrodes 116 and 118 are adapted for placing an LED 104 in electrical communication with an external circuit (not shown). As an example, an AIN(AN242) substrate body may be utilized. In an implementation, ultra-fine blind vias electrically connecting the cathode electrode 116 and the anode electrode 118 to the SMT pads 126 and 128 respectively may be formed using an ultraviolet YAG laser and a direct copper build-up process. The direct copper build-up process may be carried out, as an example, by electroplating or electroless plating or another deposition technique.

In step 506, an LED 104 may be placed on the substrate body. As an example, the LED 104 may be placed in a concave cavity 106 on the base inner wall 186. The LED 104 may be pre-made, or formed in situ. The LED 104 may be, as an example, positioned at a point on the base inner wall 186 that is substantially equidistant from all points at which the base inner wall 186 meets the side inner wall 188. The LED 104 may be fabricated using various known techniques such as, for example, liquid phase epitaxy, vapor phase epitaxy, metal-organic epitaxial chemical vapor deposition, or molecular beam epitaxy. The LED 104 may, as an example, be attached to the base inner wall 186 using a silver epoxy resin which is then cured. In another implementation, the LED 104 may as an example be attached by a gold-tin eutectic composition including a reflow step to set the LED 104 in the eutectic.

In step 508, a Top Surface Heat Dissipator is provided that may include an optically transparent body 156 and that includes an electrically and thermally conductive heat dissipator 158. In an implementation, a lens body 190 may also be formed in step 508 integrally together with or separately formed and then joined with the optically transparent body 156. As another example, the lens body 190 may be formed or attached to the optically transparent body 156 at another point in the process 500. The electrically and thermally conductive heat dissipator 158 may, as an example, be formed on a bottom surface 162 of the optically transparent body 156. In an example, a thermally conductive heat dissipator 160 may also be so formed on the bottom surface 162 of the optically transparent body 156.

One or a plurality of electrically and thermally conductive bodies 168 may be formed on the electrically and thermally conductive heat dissipator 158, positioned so as to make contact with portion 136 of the anode electrode 118 upon assembly of the LED Device Having a Top Surface Heat Dissipator 100. One or a plurality of electrically and thermally conductive bodies 170 may also be formed on the electrically and thermally conductive heat dissipator 158, positioned so as to make contact with the top conductor body 150 or the n-doped semiconductor body 146 or both upon assembly of the LED Device Having a Top Surface Heat Dissipator 100.

In another implementation, one or a plurality of thermally conductive bodies 172 may be formed on the thermally conductive heat dissipator 160, positioned so as to make contact with the portion 134 of the cathode electrode 116 upon assembly of the LED Device Having a Top Surface Heat Dissipator 100.

As an example, the electrically and thermally conductive bodies 168 and 170 and the thermally conductive body 172 may be formed of a conductive metal, such as a composition including gold, platinum, palladium, nickel, or an alloy. In an implementation, the electrically and thermally conductive bodies 168 and 170 and the thermally conductive body 172 may be formed as beads of a conductive metal composition, such as a solder for example. As another example, gold-tin eutectic pads may be substituted for solder beads.

In an implementation, the portions 136 and 134 of the anode and cathode electrodes 118 and 116 may include a nickel-tin and tin-copper-nickel intermetallic compound layer (“IMC”) layer. The electrically and thermally conductive heat dissipator 158 and the thermally conductive heat dissipator 160 may be formed of copper and may include a copper-tin IMC layer. As an example, a solder ball formed of 63/37 (weight/weight) tin-lead alloy or formed of another solder alloy such as a lead-free alloy, may be deposited onto the electrically and thermally conductive heat dissipator 158 and the thermally conductive heat dissipator 160 and placed between the IMC layers to electrically and thermally integrate them with the portions 136 and 134 of the anode and cathode electrodes 118 and 116, respectively.

In step 510, the Top Surface Heat Dissipator, including the optically transparent body 156 and the electrically and thermally conductive heat dissipator 158, may be aligned over and assembled together with the substrate body 102 so that the electrically and thermally conductive heat dissipator 158 and the thermally conductive heat dissipator 160 are in spaced apart alignment with portions 136 and 134 of the anode and cathode electrodes 118 and 116 respectively, and so that the electrically and thermally conductive heat dissipator 158 and the thermally conductive heat dissipator 160 are in communication with the electrically and thermally conductive bodies 168 and 170 and the thermally conductive body 172. Where solder beads are utilized, a solder reflow may then cause a controlled collapse of the solder beads, leaving the Top Surface Heat Dissipator in communication and in close proximity to the substrate body 102. Where gold-tin eutectic pads are utilized instead of solder beads, they may be melted to cause an analogous reflow and controlled collapse.

In step 512, the LED 104 is encapsulated. In an implementation, a filler body 176 may be formed in the cavity 174. As an example, the filler body 176 may completely fill the cavity 174 over the LED 104 and be in contact with the electrically and thermally conductive heat dissipator 158 and the thermally conductive heat dissipator 160 on the bottom surface 162 of the optically transparent body 156. In another implementation, a portion of the volume of the cavity 174 extending outside the concave cavity 106 may be partially or completely filled by another composition, such as a composition having a relatively larger heat transfer capability. The filler body 176 may be formed from, as an example, an encapsulant composition as earlier discussed. In an example, the encapsulant composition may include a phosphor as earlier discussed. As another example, an encapsulant composition including a phosphor may fill a selected region of the concave cavity 106, and an encapsulant without a phosphor may fill another selected region of the concave cavity. The encapsulant may be formed, as an example, by injecting a liquid encapsulant composition into the cavity 174. In an example, the liquid encapsulant composition may then be converted to a solid state by heat-catalyzed curing. Where multiple encapsulant regions are to be included in an LED Device Having a Top Surface Heat Dissipator 100, back filling may be done after a first encapsulant is cured. The process may then end in step 514. This process may be utilized to form an array of LED Devices Having a Top Surface Heat Dissipator 100 as an integral array which may then be separated by sawing or laser scribing as examples. It is appreciated that the order of steps in the process 500 may be changed.

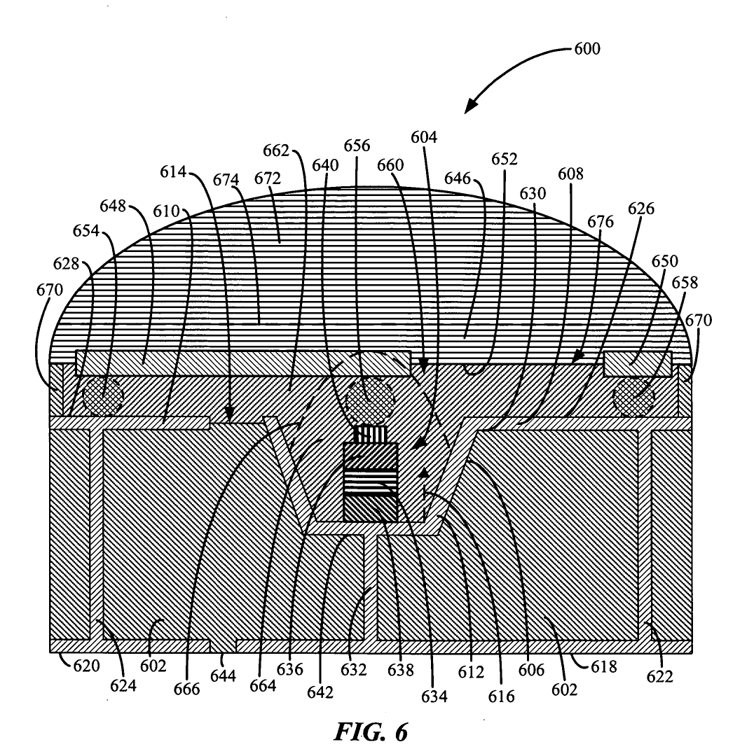

FIG. 6 is a cross-sectional view, taken on line 2-2, showing an example of an implementation of another LED Device Having a Top Surface Heat Dissipator 600 having a modified structure and the same top view, shown in FIG. 1, as the LED Device Having a Top Surface Heat Dissipator 100. The LED Device Having a Top Surface Heat Dissipator 600 includes a substrate body 602 on which an LED 604 is placed. As an example, the substrate body 602 may include a concave cavity 606, and the LED may be on the substrate body 602 in the concave cavity. The LED Device Having a Top Surface Heat Dissipator 600 may include a cathode electrode 608 and an anode electrode 610. The cathode electrode 608 may be integrated with a conductive frame 612 lining the concave cavity 606, and a gap 614 may electrically isolate the cathode electrode 608 and the anode electrode 610 from each other. The conductive frame 612 may be, as an example, optically reflective to focus light generated by the LED 604 generally in the direction of the arrow 616.

The cathode electrode 608 may include an SMT pad 618. As an example, the anode electrode 610 may include an SMT pad 620. It is understood that the respective locations of the SMT pads 618 and 620 with respect to the substrate body 602 may be varied. The cathode electrode 608 includes a connecting portion 622 embedded in the substrate body 602 placing the LED 604 in communication with the SMT pad 618; and the anode electrode 610 includes a connecting portion 624 embedded in the substrate body 602 placing the LED 604 in communication with the SMT pad 620. In another implementation, a portion 626 of the cathode electrode 608 and a portion 628 of the anode electrode 610 may each be positioned over a top surface 630 of the substrate body 602. The cathode electrode 608 may include an internal portion 632 passing between the conductive frame 612 and the SMT pad 618.

As another implementation (not shown), the concave cavity 606 may be omitted and the LED 604 may be on the top surface 630 of the substrate body 602.

The LED 604 may include a p-doped semiconductor body 634 and an n-doped semiconductor body 636. The shape of the LED 604 may be a rectangular prism, cubic, cylindrical, or have another selected geometric shape in the same manner as discussed above in connection with the LED 104 shown in FIG. 1. In an implementation, more than one LED 604 may be placed in the concave cavity 606.

The p-doped semiconductor body 634 may be in electrical communication with a base conductor body 638 and the n-doped semiconductor body 636 may be in electrical communication with a top conductor body 640. It is appreciated that in an alternative example structure for the LED Device Having a Top Surface Heat Dissipator 600, the semiconductor body 636 may be p-doped and the semiconductor body 634 may be n-doped. As another example, the cathode electrode 608 may be replaced by a first terminal electrode 608 at a relatively high electrical potential in electrical communication with the p-doped semiconductor body 634; and the anode electrode 610 may be replaced by a second terminal electrode 610 at a relatively low electrical potential in electrical communication with the n-doped semiconductor body 636.

A perimeter of the substrate body 602 may be square, circular, elliptical, pentagonal, or hexagonal, as examples, in the same manner as discussed above in connection with the perimeter 152 of the substrate body 102. In an example (not shown), a bottom surface 642 of the conductive frame 612 lining the concave cavity 606 may be exposed adjacent to a bottom surface 644 of the substrate body 602 so that heat may be conducted away from the LED 604.

The LED Device Having a Top Surface Heat Dissipator 600 may further include an optically transparent body 646 positioned over the LED 604, the portion 626 of the cathode electrode 608, the portion 628 of the anode electrode 610, and the top surface 630 of the substrate body 602. The optically transparent body 646 may be formed of a composition selected for high transmission and low absorbance of the light wavelength or wavelengths emitted by the LED 604, and of light wavelengths emitted by a phosphor in an example where the LED Device Having a Top Surface Heat Dissipator 600 may be a phosphor-conversion device.

An electrically and thermally conductive heat dissipator 648 may be integrated with the optically transparent body 646 and spaced apart in partial alignment over and facing the portion 628 of the anode electrode 610. The electrically and thermally conductive heat dissipator 648 is also spaced apart in partial alignment over and facing the top conductor body 640. A thermally conductive heat dissipator 650 may be integrated with the optically transparent body 646 and spaced apart in partial alignment over and facing the portion 626 of the cathode electrode 608. As an example, the electrically and thermally conductive heat dissipator 648 and the thermally conductive heat dissipator 650 may be partially or completely embedded into a bottom surface 652 of the optically transparent body 646 facing the top surface 630 of the substrate body 602. In another implementation, not shown, the electrically and thermally conductive heat dissipator 648 and the thermally conductive heat dissipator 650 may be formed on the bottom surface 652 of the optically transparent body 646.

As an example, the electrically and thermally conductive heat dissipator 648 and the thermally conductive heat dissipator 650 may be formed from compositions selected for optical transparency or from opaque compositions such as a metal or a metal alloy, in the same manner as discussed above in connection with the electrically and thermally conductive heat dissipator 158 and the thermally conductive heat dissipator 160 shown in FIG. 2. As an implementation where such an opaque composition may be utilized, trace widths (not shown) of the electrically and thermally conductive heat dissipator 648 and the thermally conductive heat dissipator 650 may be minimized as discussed earlier in connection with FIGS. 2 and 4.

One or a plurality of electrically and thermally conductive bodies 654 may be formed in contact with the portion 628 of the anode electrode 610 and with the electrically and thermally conductive heat dissipator 648. One or a plurality of electrically and thermally conductive bodies 656 may be formed in contact with the top conductor body 640 or with the semiconductor body 636 or both, and with the electrically and thermally conductive heat dissipator 648. The electrically and thermally conductive heat dissipator 648 provides an electrical connection between the top conductor body 640 or the semiconductor body 636 or both and the anode electrode 610. The electrically and thermally conductive body 656 provides a pathway for dissipation of heat through the electrically and thermally conductive heat dissipator 648.

As another implementation (not shown), the electrically and thermally conductive body 656 may be embedded in the electrically and thermally conductive heat dissipator 648 or in the optically transparent body 646 or both. In another implementation, the electrically and thermally conductive body 656 may be embedded in the top conductor body 640 or in the semiconductor body 636 or both.

As another example, the electrically and thermally conductive heat dissipator 648 may have a shape (not shown) placing the heat dissipator 648 in direct electrical and thermal communication with the top conductor body 640 or the semiconductor body 636, and the portion 628 of the anode electrode 610. In that example, the electrically and thermally conductive bodies 656 and 654 may be omitted.

In another example, one or a plurality of thermally conductive bodies 658 may be formed in contact with the portion 626 of the cathode electrode 608 and with the thermally conductive heat dissipator 650. The thermally conductive body 658 may receive heat from the LED 604 originating along pathways including a pathway via the conductive frame 612 in contact with the base conductor body 638, and may conduct heat to the thermally conductive heat dissipator 650 for dissipation through the optically transparent body 646.

As a further implementation, the thermally conductive heat dissipator 650 may have a shape (not shown) placing the heat dissipator 650 in direct thermal communication with the portion 626 of the cathode electrode 608, and the electrically and thermally conductive body 658 may be omitted.

As examples, the electrically and thermally conductive bodies 654 and 656 and the thermally conductive body 658 may each be formed as a solder bump, a solder paste coating, or an anisotropic conductive film (ACF).

As an example, the top surface 630 of the substrate body 602, the portion 628 of the anode electrode 610, the portion 626 of the cathode electrode 608, the conductive frame 612, the bottom surface 652 of the optically transparent body 646, the electrically and thermally conductive heat dissipator 648, and the thermally conductive heat dissipator 650, may together form a cavity 660. In an implementation, the cavity 660 may be completely or partially filled by a filler body 662. In an example, the filler body 662 may be formed from a thermally conductive and electrically insulating composition that provides additional pathways for conduction of heat generated by the LED 604 to the electrically and thermally conductive heat dissipator 648, the thermally conductive heat dissipator 650, and the optically transparent body 646.

The filler body 662 may be formed of a composition having selected optical transmittance as discussed above in connection with the filler body 176 shown in FIG. 2. In another example, the filler body 662 may include a first stage optically transparent filler body 664 located as an example surrounding the LED 604 and extending to the dotted line 666; and a second stage thermally conductive filler body in the remaining portion of the cavity 660 outside the dotted line 666. In an implementation, the first stage optically transparent filler body 664 may make contact with the electrically and thermally conductive heat dissipator 648.

In an example, the optically transparent body 646 may be spaced apart by a raised region 670 of the substrate body 602 from the portion 626 of the cathode electrode 608 and from the portion 628 of the anode electrode 610. As another example, the raised region 670 may be omitted.

The concave cavity 606 may form a reflector for photons emitted by the LED 604. The concave cavity 606 may include a base inner wall and a side inner wall having shapes selected as discussed above in connection with the base inner wall 186 and the side inner wall 188 shown in FIG. 2.

As an example, a lens body 672 may be formed over and in contact with the optically transparent body 646 at an interface indicated by the dotted line 674. The lens body 672 may serve to further focus the photonic emissions from the LED Device Having a Top Surface Heat Dissipator 600. In an implementation, the lens body 672 and the optically transparent body 646 may be integrally formed of a composition having selected optical transmittance. As another example, the lens body 672 may be a diffused lens, which may include dispersed light-scattering particles as discussed in connection with FIG. 2.

The substrate body 602 may be formed of a composition selected in the same manner as discussed above in connection with the substrate body 102 shown in FIG. 2.

The electrically and thermally conductive heat dissipator 648 and the thermally conductive heat dissipator 650 may be formed of a composition selected in the same manner as discussed earlier in connection with the electrically and thermally conductive heat dissipator 158 and the thermally conductive heat dissipator 160, respectively. In an implementation, the thermally conductive heat dissipator 650 may be electrically conductive, a gap 676 may be interposed between the electrically and thermally conductive heat dissipator 648 and the thermally conductive heat dissipator 650, and the optically transparent body 646 may be formed of a composition having a selected high dielectric constant.

The optically transparent body 646 may be formed of a composition selected in the same manner as discussed earlier in connection with the optically transparent body 156 shown in FIG. 2. The LED 604 may be selected as discussed earlier in connection with the LED 104 shown in FIG. 2.

As a further example, the LED Device Having a Top Surface Heat Dissipator 600 may be a phosphor-converting LED device having a selected phosphor composition dispersed in a region of or throughout the filler body 662 in the same manner as discussed earlier in connection with the LED Device Having a Top Surface Heat Dissipator 100.

The LED Device Having a Top Surface Heat Dissipator 600 may be fabricated by the process shown in FIG. 5 and discussed in connection with the LED Device Having a Top Surface Heat Dissipator 100, except that step 504 includes providing a substrate body 602 including a cathode electrode 608 that includes a connecting portion 622 embedded in the substrate body 602 placing the LED 604 in communication with the SMT pad 618, and an anode electrode 610 that includes a connecting portion 624 embedded in the substrate body 602 placing the LED 604 in communication with the SMT pad 620.

While the foregoing description refers to LED devices having various SMT and through-hole structures, it is understood that the subject matter is not limited to the structures shown in the figures. Other electrode configurations and other LED device structures that include thermally conductive bodies and electrically and thermally conductive bodies having different shapes and locations suitable to conduct heat away from an LED and toward the optically transparent body are included. Although some examples use an LED emitting blue photons to stimulate luminescent emissions from a yellow phosphor in order to produce output light having a white appearance, the subject matter also is not limited to such a device. Any LED device that may benefit from the heat dissipating functionality provided by the structures described above may be utilized as an LED Device Having a Top Surface Heat Dissipator as disclosed herein and shown in the drawings.

Moreover, it will be understood that the foregoing description of numerous implementations has been presented for purposes of illustration and description. This description is not exhaustive and does not limit the claimed inventions to the precise forms disclosed. Modifications and variations are possible in light of the above description or may be acquired from practicing the invention. The claims and their equivalents define the scope of the invention.

What is claimed:

1. An LED Device Having a Top Surface Heat Dissipator, comprising:
a substrate body;
a light emitting diode (“LED”) over the substrate body;
an electrically and thermally conductive heat dissipator over the substrate body.

2. The LED Device Having a Top Surface Heat Dissipator of claim 1, including an optically transparent body over the electrically and thermally conductive heat dissipator.

3. The LED Device Having a Top Surface Heat Dissipator of claim 2, wherein the electrically and thermally conductive heat dissipator is in thermal communication with the optically transparent body.

4. The LED Device Having a Top Surface Heat Dissipator of claim 1, wherein the electrically and thermally conductive heat dissipator is in electrical and thermal communication with the LED.

5. The LED Device Having a Top Surface Heat Dissipator of claim 1 including an LED anode, wherein the electrically and thermally conductive heat dissipator is in electrical and thermal communication with the LED anode.

6. The LED Device Having a Top Surface Heat Dissipator of claim 5, including an electrically and thermally conductive body in electrical and thermal communication with the LED anode and with the electrically and thermally conductive heat dissipator.

7. The LED Device Having a Top Surface Heat Dissipator of claim 5, including an electrically and thermally conductive body in electrical and thermal communication with the LED and with the electrically and thermally conductive heat dissipator.

8. The LED Device Having a Top Surface Heat Dissipator of claim 5, including a surface mount anode pad in electrical and thermal communication with the electrically and thermally conductive heat dissipator.

9. The LED Device Having a Top Surface Heat Dissipator of claim 1 including a thermally conductive heat dissipator over the substrate body and including an LED cathode, wherein the thermally conductive heat dissipator is in thermal communication with the LED cathode.

10. The LED Device Having a Top Surface Heat Dissipator of claim 9, including a thermally conductive body in thermal communication with the LED cathode and with the thermally conductive heat dissipator.

11. The LED Device Having a Top Surface Heat Dissipator of claim 5 including a thermally conductive heat dissipator over the substrate body and including an LED cathode, wherein the thermally conductive heat dissipator is in thermal communication with the LED cathode.

12. The LED Device Having a Top Surface Heat Dissipator of claim 1, wherein the substrate body includes a concave cavity, and the LED is over the substrate body in the concave cavity.

13. The LED Device Having a Top Surface Heat Dissipator of claim 1, including a thermally conductive filler body interposed between the substrate body and the electrically and thermally conductive heat dissipator.

14. The LED Device Having a Top Surface Heat Dissipator of claim 1, including an optically transparent filler body interposed between the LED and the electrically and thermally conductive heat dissipator.

15. A method of dissipating heat from an LED device, comprising: forming an LED Device Having a Top Surface Heat Dissipator including a substrate body, a light emitting diode (“LED”) over the substrate body, and an electrically and thermally conductive heat dissipator over the substrate body; and dissipating heat generated by the LED through the electrically and thermally conductive heat dissipator.

16. The method of claim 15, including forming an optically transparent body over the electrically and thermally conductive heat dissipator.

17. The method of claim 16, including placing the electrically and thermally conductive heat dissipator in thermal communication with the optically transparent body.

18. The method of claim 15, including placing the electrically and thermally conductive heat dissipator in electrical and thermal communication with the LED.

19. The method of claim 15, including forming an LED anode, and placing the electrically and thermally conductive heat dissipator in electrical and thermal communication with the LED anode.

20. The method of claim 15, including forming a thermally conductive heat dissipator over the substrate body, forming an LED cathode, and placing the thermally conductive heat dissipator in thermal communication with the LED cathode.
